(19) United States
(12) Patent Application Publication
(10) Pub. No.: US 2024/0429469 A1
(43) Pub. Date: Dec. 26, 2024

(54) BATTERY MANAGEMENT SYSTEM WITH LOW LATENCY

(71) Applicant: REON Technology, Inc., Chelmsford, MA (US)

(72) Inventors: Tiegeng Ren, Westford, MA (US); Xuanhang Zhang, Austin, TX (US)

(73) Assignee: REON Technology, Inc., Chelmsford, MA (US)

(21) Appl. No.: 18/823,772

(22) Filed: Sep. 4, 2024

Related U.S. Application Data
(63) Continuation-in-part of application No. 18/385,439, filed on Oct. 31, 2023.
(63) Continuation-in-part of application No. 18/137,471, filed on Apr. 21, 2023.
(63) Continuation-in-part of application No. 18/115,811, filed on Mar. 1, 2023.
(60) Provisional application No. 63/666,285, filed on Jul. 1, 2024.
(60) Provisional application No. 63/536,514, filed on Sep. 5, 2023.
(60) Provisional application No. 63/534,791, filed on Aug. 25, 2023.
(60) Provisional application No. 63/422,464, filed on Nov. 4, 2022.
(60) Provisional application No. 63/334,160, filed on Apr. 24, 2022.
(60) Provisional application No. 63/333,708, filed on Apr. 22, 2022.
(60) Provisional application No. 63/334,160, filed on Apr. 24, 2022.
(60) Provisional application No. 63/334,106, filed on Apr. 23, 2022.
(60) Provisional application No. 63/333,708, filed on Apr. 22, 2022.
(60) Provisional application No. 63/315,550, filed on Mar. 2, 2022.

(51) Int. Cl. H01M 10/42; G01R 31/367; G01R 31/382; H01M 10/48

(52) U.S. Cl. CPC H01M 10/425; G01R 31/367; G01R 31/382; H01M 10/482; H01M 2010/4271; H01M 2010/4278

(57) ABSTRACT

A processor-implemented method for battery management is disclosed. A plurality of battery units can be accessed. Each battery unit can contain one or more battery cells and can be configured using programmable switches. The battery units can be monitored by battery sensors and scanned to collect battery unit information. The battery unit information can be stored in local caches located on each unit. The battery unit information can be reported from the local caches to a master controller, which stores the information in a system cache. The reporting can be triggered by a change in the battery unit information. The battery information can be analyzed and used to determine a battery unit metric stored in a register map. Additional battery unit information can be analyzed and compared to the battery unit metric. Based on changes in the battery unit information, the master controller can modify the battery unit configuration.

### RELATED APPLICATIONS

This application claims the benefit of U.S. provisional patent applications “Battery Management System With Low Latency” Ser. No. 63/536,514, filed Sep. 5, 2023, and “Battery Management System With In Situ Cell Rejuvenation” Ser. No. 63/666,285, filed Jul. 1, 2024.

This application is also a continuation-in-part of U.S. patent application “Software-Defined Energy Storage System Interface” Ser. No. 18/115,811, filed Mar. 1, 2023, which claims the benefit of U.S. provisional patent applications “Software-Defined Energy Storage System Interface” Ser. No. 63/334,106, filed Apr. 23, 2022, “Battery System Management Using Cell State” Ser. No. 63/333,708, filed Apr. 22, 2022, “Battery Performance Tracking Across Battery Cells” Ser. No. 63/334,160, filed Apr. 24, 2022, and “Dynamic Control Of A Disparate Battery System” Ser. No. 63/315,550, filed Mar. 2, 2022.

This application is also a continuation-in-part of U.S. patent application “Battery Performance Tracking Across Battery Cells” Ser. No. 18/137,471 filed Apr. 21, 2023, which claims the benefit of U.S. provisional patent applications “Battery System Management Using Cell State” Ser. No. 63/333,708, filed Apr. 22, 2022, and “Battery Performance Tracking Across Battery Cells” Ser. No. 63/334,160, filed Apr. 24, 2022.

This application is also a continuation-in-part of U.S. patent application “Battery Management System With Controlled Replacement” Ser. No. 18/385,439, filed Oct. 31, 2023, which claims the benefit of U.S. provisional patent applications “Battery Management System With Controlled Replacement” Ser. No. 63/422,464, filed Nov. 4, 2022, “Distributed Power System For Management And Control” Ser. No. 63/534,791, filed Aug. 25, 2023, and “Battery Management System With Low Latency” Ser. No. 63/536,514, filed Sep. 5, 2023.

Each of the foregoing applications is hereby incorporated by reference in its entirety.

### FIELD OF ART

This application relates generally to battery management and more particularly to a battery management system with low latency.

### BACKGROUND

In modern times, one of the most important and influential scientific discoveries has been the properties and various uses of electricity. Humans have been aware of electrical phenomena for millennia. Ancient Egyptians, as far back as 2750 BC, described fish capable of delivering shocks. Ancient Greek, Roman, and Arabic naturalists and physicians made similar observations many years later. Some ancient cultures found that certain objects could store static electricity charges when rubbed against other objects such as cat fur. Around 600 BC, Thales of Miletus wrote about minerals that had magnetic properties and compared them to other objects that seemed to store electrical charges. This appears to be the first time an observer linked magnetism and electricity. Not until 1600 AD, when William Gilbert of England published a work entitled, “De Magnete”, did electricity and magnetism begin to be carefully studied and their properties researched for possible uses. The first time the words “electric” and “electricity” appeared in print was in 1646 in a work by another Englishman, Thomas Browne. Other scientists followed in the 1700s. Benjamin Franklin, Otto von Guericke, Robert Boyle, Stephen Gray, Hugh Williamson, and others published works describing various observations and experiments with electricity. In 1791, Luigi Galvani demonstrated that electricity was the means by which neurons pass signals to muscles. In 1800, Alessandro Volta created a voltaic pile, or battery, made from alternating layers of zinc and copper. This battery proved to be the most reliable source of electrical energy to that point in time. The relationship between magnetism and electricity (electromagnetism) was scientifically described and demonstrated by Ørsted and Ampère in the early 1800s. Soon after, Michael Faraday invented the electric motor and Georg Ohm mathematically analyzed the electrical circuit.

With many of the basics of electricity and its relationship to magnetic fields and to light described, the latter half of the 19^{th} century exploded with new discoveries and inventions that moved electricity from a curiosity to a tool with many uses. In 1905, Albert Einstein published a paper explaining the photoelectric effect, which led to a revolution in the understanding of quantum physics. Solid-state components followed soon thereafter with the emergence of transistors in the 1940s. Among the many inventions and tools related to electricity, batteries are easily one of the most commonly used and relied upon. Volta's original electric cell was a good starting point, but others soon improved on it. Inventors and scientists across Europe experimented with various elements and liquid media, trying to find the best combinations of metals and soluble salts, acids, or bases to produce reliable and predictable sources of electrical current. By the 1880s, Planté and Faure had developed lead-acid batteries that could be recharged using a reverse current. Such batteries are still used today in cars, boats, and other applications where weight is not a significant factor. Around the same time, the zinc-carbon dry cell battery was developed and became the first convenient battery for use by consumers in many portable electrical devices, such as flashlights. Soon after, the first alkaline battery using nickel and cadmium was perfected. This dry cell battery has the advantage of being rechargeable, but is also significantly more expensive to produce. Other combinations of rechargeable and single-use batteries have been developed and marketed in recent years. Nickel-hydrogen, nickel-cadmium, and lithium batteries have all been successfully used in many applications. As a practical component for thousands of electrical tools and other applications, batteries continue to be an essential part of modern life and will be for many years to come.

### SUMMARY

Rechargeable batteries are ubiquitous in our modern life. They are used in everything from personal cell phones, tablets, and computers to electric vehicles and power grids. Varying design and chemical compositions of the rechargeable batteries result in different lifespans and performance characteristics for the batteries. Eventually, the batteries begin to break down and cannot be recharged. The in-service rechargeable batteries are removed, and other rechargeable batteries are installed in their places. Rechargeable batteries that are removed from service can be problematic. Batteries can leak their chemicals, become unstable, or even catch fire and explode. Recycling of rechargeable batteries is encouraged, but recycling the chemicals and materials used to construct the batteries can be costly and complicated. Many of the rechargeable batteries that are removed from service can still be used in some power storage applications. While they may not perform at the same level as when they were new, they can still be used to store and discharge electrical energy. Groups of rechargeable batteries can be collected, scanned, and analyzed to determine their performance qualities including temperature, voltage, current, impedance, and so on. In order to use the batteries for new power applications, the batteries can be broken down into their component cells. Switches and scanners or sensors can be added to the cells to select or deselect the cells, to monitor cell “health”, and so on. The cells can be assembled into battery units, and the battery units can be coupled into battery systems. The battery cells can be selected when in use by the battery system or for recharging, or deselected when the cell is unneeded in a particular battery system or when the cell is inadequate to the task. Frequent monitoring of the cells can detect problems with one or more cells such as overheating, a short circuit, etc. Thus, problematic cells can be quickly removed from service and safely discharged, thereby reducing or eliminating the risk of fire or explosion.

Battery management is based on dynamic control of a disparate battery system. A plurality of battery units is accessed, wherein the battery units contain one or more battery cells. The battery cells are configured with programmable switches and are monitored by one or more battery sensors. The battery sensors monitor the performance characteristics of the battery cells as they are used. Each battery unit includes a controller that scans the various sensors and records the performance data to a local memory cache. A master controller that is in communication with all of the local battery unit controllers receives performance information from each of the local controllers and stores the data in a system memory cache. The master controller can configure groups of battery units to perform various electrical service requests and to monitor the performance of the various battery units within each configuration to ensure that performance requirements are maintained. A heartbeat poll signal is generated by the master controller and can be used to monitor the performance of the battery units. If a battery unit begins to fail or perform outside of the parameters required for a particular configuration, the master controller can trigger reconfiguration of appropriate switches connected to each battery unit to remove the failing unit from an active configuration and to notify users to replace the unit. Likewise, the local controller on each battery unit can remove itself from the active configuration if the heartbeat poll signal is not received or local performance parameters fall below specifications. The master controller can add or remove battery units as needed to maintain the performance requirements of one or more configurations, depending on the number of battery units in the system.

A computer-implemented method for battery management is disclosed comprising: accessing a plurality of battery units, wherein the battery units contain one or more battery cells, wherein the plurality of battery units is configured using programmable switches, and wherein the battery units are each monitored by one or more battery sensors; scanning the battery units within the plurality of battery units to collect battery unit information; storing the battery unit information in local caches, wherein each of the plurality of battery units has a local cache; reporting the battery unit information from each of the local caches to a master controller, wherein the master controller stores the battery unit information in a system cache, and wherein the reporting is triggered by a change in the battery unit information; analyzing the battery unit information, wherein the analyzing determines a battery unit metric; and modifying the battery unit configuration, based on the metric. In embodiments, the system cache implements a register map. In embodiments, the register map corresponds to battery units. Some embodiments comprise coupling a battery unit controller to each battery unit of the plurality of battery units. In embodiments, the battery unit controller implements a heartbeat timer. In embodiments, the heartbeat timer is programmable by the master controller.

Various features, aspects, and advantages of various embodiments will become more apparent from the following further description.

### BRIEF DESCRIPTION OF THE DRAWINGS

The following detailed description of certain embodiments may be understood by reference to the following figures wherein:

FIG. 1 is a flow diagram for a battery management system with low latency.

FIG. 2 is a flow diagram for battery unit handling.

FIG. 3 is a system block diagram for battery management with low latency.

FIG. 4 illustrates battery unit replacement completion.

FIG. 5 is a system block diagram for managing controlled replacement.

FIG. 6 illustrates columns of battery cells and switches in a battery system.

FIG. 7 is a flow diagram for battery system control.

FIG. 8 is a system diagram for a battery management system with low latency.

### DETAILED DESCRIPTION

A processor-implemented technique for a battery management system with low latency is disclosed. Batteries of all kinds are found in a vast array of modern products. From personal care items to handheld electronic devices to vehicles, batteries are used to power convenient and often portable use of these and many other devices. As the use of electronic devices and electric vehicles has become more prevalent, and the limitations of traditional battery technologies have proven too limiting for practical use, researchers have sought advanced battery chemistries and configurations. More advanced batteries are finding increasing use in applications such as renewable energy storage, transportation, and personal electronic devices. Batteries are now used to provide power to power grids when renewable sources are offline, to terrestrial vehicles, and soon to anal vehicles as well. However, rechargeable batteries age over time, primarily due to charge/discharge cycling. In order to maintain operation of electrical equipment, electric vehicles, and electronic devices at manufacturer specifications, the rechargeable batteries require replacement. The replacement is indicated once the charge-discharge cycle limit has been reached, or at any time if one or more of the batteries encounter a problem. The in-service rechargeable batteries are removed and replaced with other rechargeable batteries. Rechargeable batteries that are removed from service are typically sent for recycling. The batteries that were removed may no longer operate at their original storage and discharge levels, but they can still store and provide electrical energy storage and distribution for other applications.

Rechargeable batteries that are removed from their original service uses can be provided a “second life”. The rechargeable batteries can be scanned to collect performance information. The performance information can be collected while the batteries are in use and can include data associated with temperature, current, voltage, impedance, and so on. The batteries can be further analyzed to determine usability and capacity. In order to use the batteries for new power applications, the batteries can be broken down into their component cells. Switches and scanners or sensors can be added to the cells to select or deselect the cells, to monitor cell “health”, and so on. The cells can be assembled into battery units, and the battery units can be coupled into battery systems. The battery cells can be selected when in use by the battery system or for recharging, or deselected when the cell is unneeded in a particular battery system or when the cell is inadequate to the task. Frequent monitoring of the cells can detect problems with one or more cells, such as overheating, a short circuit, etc. Thus, problematic cells can be quickly removed from service and safely discharged, thereby reducing or eliminating the risk of fire or explosion.

A battery system including battery units with sensors and switches can be managed with a master controller, capable of configuring groups of battery units into multiple configurations to deliver power within specified performance and safety parameters. Controllers located on each battery unit can scan sensors placed on the battery units to monitor critical performance measurements of temperature, current, voltage, and so on. The local controllers can store performance data in local caches and can forward the data to a system cache tied to the master controller as needed. The master controller can generate a heartbeat poll signal to continuously monitor the condition of each battery unit in active configurations. The heartbeat poll can be used to quickly determine a change in the health of one or more battery units and respond by disconnecting battery units that have failed and connecting other battery units held in reserve. This maintains the integrity and performance characteristics of each active configuration. A report-only-at-change response mechanism can be used to minimize traffic between the battery unit controllers and the master controller. Likewise, a late or missed heartbeat poll signal from the master controller can cause a battery unit to disconnect itself from the active configuration, causing the master controller to bring a replacement battery cell online. The communication backbone used with the heartbeat poll signal can have a scan rate of more than 500 Hz, allowing for a scan to be completed every 2 milliseconds. This allows for a high degree of stability in the performance of each active battery unit configuration maintained by the master controller, as well as low latency in determining and remedying battery unit failures when they occur.

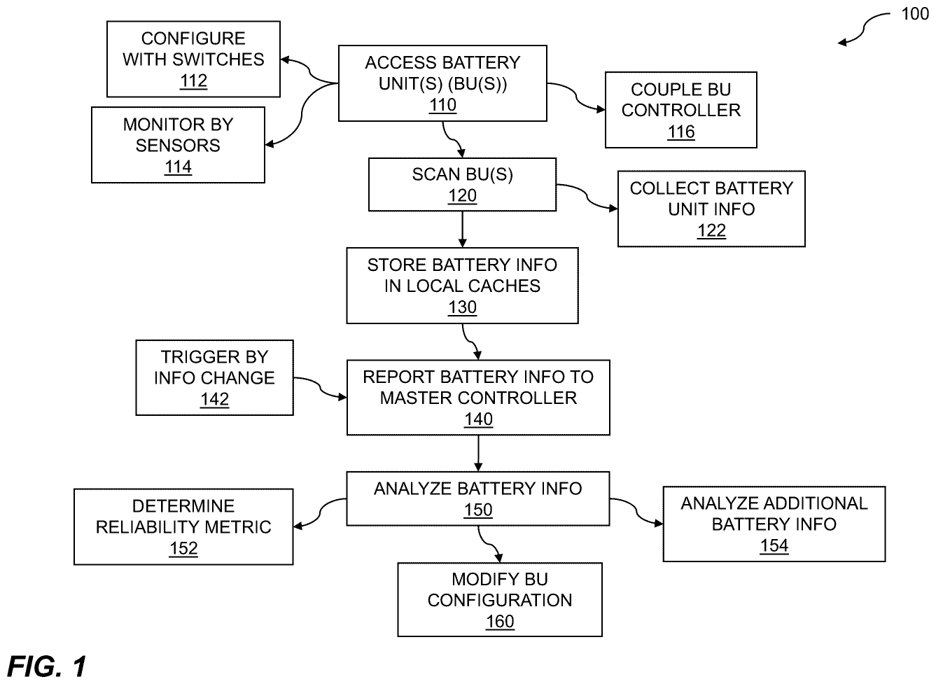

FIG. 1 is a flow diagram for a battery management system with low latency. The flow 100 includes accessing a plurality of battery units 110, wherein the battery units (BUs) contain one or more battery cells, wherein the plurality of battery units is configured using programmable switches 112, and wherein the battery units are each monitored by one or more battery sensors 114. In embodiments, the plurality of battery cells can include homogeneous battery cells, heterogeneous battery cells, and so on. The battery cells can include substantially similar physical dimensions, a mixture of battery cells with substantially different physical dimensions, etc. The battery cells, which can include rechargeable battery cells, can include a variety of battery types. In embodiments, the one or more battery cells can include lithium-ion battery cells. Other types of rechargeable cells, such as sealed lead-acid (SLA), nickel-cadmium (NiCd), nickel-metal hydride (NiMH), lithium-polymer (LiPo), lithium-iron-phosphate (LiFePO4), sodium-ion, lithium-metal, solid-state, sodium ion, zinc based, etc., can be included.

In embodiments, programmable switches 112 can be configured with the battery units. The switches can be used to couple, decouple, and bypass the battery units. The switches can include a series switch and a bypass switch for each battery unit (described below) The battery sensors 114 can be used to monitor battery performance information such as temperature, current, voltage, or impedance data. The programmable switches, which are based on high-speed switching devices, and the sensors can be monitored and controlled by a master controller in order to operate the battery cells, battery units, and battery systems at their most efficient and safest levels. The safe battery levels can be monitored by a master controller that monitors battery levels and selectively disconnects battery units from the battery system before a battery unit failure. The master controller can direct the programmable switches to couple specific battery units or groups of battery units to achieve desired configurations. The battery cells and units can be monitored frequently in order to quickly respond to any detected problems.

In embodiments, the plurality of battery units, battery sensors, battery switches, and a master controller can be combined to comprise a battery system. A battery system comprised of any combination of new or used battery units can be configured by a master controller using electronically controlled switches. The switches can connect the battery units into columns of units connected in series. The switches can also connect the columns in parallel to comprise the battery system. The electronically controlled switches can further connect or bypass each battery unit. The connecting can be accomplished using series switches that connect or disconnect battery unit terminals to a power bus. The bypassing can be accomplished using a shunt switch to bypass the battery unit. The connecting or bypassing can be based on a power system configuration, where the configuration includes voltage and current levels, run times, etc. Battery unit performance information can be obtained on the battery units within the battery system including battery unit profile, safety information, temperature, current, voltage, impedance, charge/discharge cycle count, and so on. Information on the battery system can be provided by local controllers within each battery unit to the master controller. The master controller can reconfigure the battery system in situ to match management system load requirements. The battery system reconfiguration can be based on removing, replacing, or adding battery units; power request parameters; and so on.

The flow 100 further comprises coupling a battery unit controller 116 to each battery unit of the plurality of battery units 110. The battery unit controller can implement a heartbeat timer. A heartbeat is a periodic signal generated by hardware or software such as the battery master controller. The heartbeat signal can be used to indicate normal operation or to synchronize functions within a system. For example, the master controller can send a heartbeat poll signal to battery unit 1, in essence asking, “Are you OK?”. In some embodiments, the local battery unit can reply with a “Yes” or “No”. In some embodiments, the local battery unit can reply with the most recent set of sensor values, or with one or more sensor values that have changed from the previous status check. The heartbeat request can be sent from the master controller to the battery unit within a specific length of time, and the response can come back from the battery unit within a specific length of time as well. A late response from the battery unit can be interpreted as a no response, and the master controller can send signals to the appropriate switches to remove the battery unit from the active battery system configuration. Likewise, a late heartbeat signal from the master controller can also be interpreted as a fault in the battery system, leading to the battery unit activating switches to remove itself from the active battery configuration. The heartbeat timer can be programmed by the master controller. The heartbeat timer can be reset upon receiving a poll from the master controller. The battery unit controller can initiate a battery unit bypass operation, based on heartbeat timer expiration, further comprising reconfiguring the plurality of battery units to accommodate the results of the bypass operation. A plurality of battery units can be shut down, based on lost communication with one or more of the battery unit controllers.

The flow 100 includes scanning 120 the battery units within the plurality of battery units to collect battery unit information 122. In embodiments, the scanning can be used to collect performance information associated with the battery units. The performance information can include various types of data associated with the battery units. In embodiments, the performance information can include temperature, current, voltage, or impedance data. The performance data can be collected prior to configuring a battery system, while a battery system is in use, and so on. The performance information can be evaluated at various levels including a battery cell, a battery column, the battery system, etc. Obtaining information can be accomplished by software-controlled switches, smart switches, scanners, sensors, etc.; can be added to the cells to monitor cell “health”; and so on. In some embodiments, the obtaining information can be based on using battery cell profiles. The battery profiles can be based on manufacturer specifications, acceptance testing, in situ system testing, collected sensor information, specified or collected electrical characteristics, specified or collected physical characteristics, and so on. In embodiments, the scanning can occur at a frequency greater than 500 Hz. This scan rate can allow each scan cycle to be completed in 2 milliseconds.

The flow 100 includes storing 130 the battery unit information in local caches, wherein each of the plurality of battery units has a local cache. A cache is a hardware or software component that can store data in memory for rapid access at a later time. As mentioned above, battery unit information can be collected by battery unit controllers associated with each of the battery units. The local controllers can collect sensor data from sensors associated with the battery units. The battery unit characteristics can be used to generate battery unit profiles, where the profiles can be used to store information about the battery units. Information obtained from the battery system can include temperature, current, voltage, impedance, number of cycles, and so on. The most recent value for each of these characteristics can be stored in the local cache and updated as the various sensors on the battery unit monitor battery performance. In some embodiments, the values of previous cycles can be stored in cache memory as well for comparison. The battery performance values can also be forwarded to the master controller when requested, or when a change in one or more battery characteristics varies by a predetermined amount. For example, the predetermined amount of variation could include a change in the temperature of the battery unit by more than 2 degrees, or a change in voltage by more than 0.5 volts.

The flow 100 includes reporting 140 the battery unit information from each of the local caches to a master controller, wherein the master controller stores the battery unit information in a system cache, and wherein the reporting is triggered by a change 142 in the battery unit information. In embodiments, the system cache implements a register map. A register map is a dedicated memory area that contains values such as temperature, current, voltage, etc. The register map corresponds to the one or more battery units. The system cache implements a last in first out (LIFO) data structure for the register map. Each battery unit is assigned a set of registers in which the most recent value of each battery unit performance characteristic is stored. On startup of the battery units and master controller, the master controller can poll all of the battery units to collect each performance value and record these values in the register map. More than one set of values can be stored for each battery unit in the register map. The LIFO data structure of the register map can be used to ensure that the most recent value for each performance value of each battery unit is the first value available for the master controller to read.

In embodiments, the reporting is performed by the system cache. Triggers for the reporting can be based on one or more threshold settings. The one or more threshold settings can be provided at a battery unit granularity. The one or more threshold settings can also be provided at a sensor granularity. Once performance values have been stored in the master controller register map and the local cache for each battery unit, the heartbeat polling timer can be used to poll each battery unit, for example, every 2 milliseconds (ms), to check for any significant changes in any of the performance values. In some embodiments, when the sensors on the one or more battery units have not recorded a performance change, the local controller on the battery unit can reply “No Change” to the heartbeat poll request from the master controller. The heartbeat poll timer is then reset, and the master controller moves on to the next battery unit in the heartbeat polling cycle. In some embodiments, the local controller can report the most recent set of sensor readings to the master controller. The master controller can then compare the current sensor values to the values in its system cache, and can move forward if nothing has changed or remove the battery unit from the active configuration if there is a problem.

The flow 100 includes analyzing 150 the battery unit information, wherein the analyzing determines 152 a battery reliability metric. In embodiments, the analyzing component can be used to analyze the battery units to determine usability and capacity based on the performance information. The usability and capacity data can be included in the battery profiles. The usability data can include whether a battery unit is available for configuration in a battery system, whether the battery unit has physical integrity, etc. The capacity data of the battery unit can include remaining capacity. The remaining capacity can be based on a percentage, a value, a threshold, and so on. The battery unit metric can comprise a functional metric. The battery unit metric can comprise a reliability metric. As the battery units continue to be used in various configurations, additional battery information 154 can be analyzed and compared to the battery profile. As battery unit performance values and characteristics are recorded by sensors and reported to the master controller, the reliability and remaining capacity of each battery unit can be calculated and reported to users.

The flow 100 includes modifying 160 the battery unit configuration, based on the metric. In embodiments, a battery unit can be removed from active service when one or more performance metrics fall below a predetermined threshold, or when a heartbeat poll response is too slow or non-existent. As mentioned above, the programmable switches on each battery unit can be used to connect or bypass each battery unit, based on the configuration set by the master controller. The connecting or bypassing can be based on a power system configuration, where the configuration includes voltage and current levels, run times, etc. Battery unit performance information, including battery unit profile, safety information, temperature, current, voltage, impedance, charge/discharge cycle count, and so on, can be obtained on the battery units within the battery system. Information on the battery system can be provided by local controllers within each battery unit to the master controller. The master controller can reconfigure the battery system in situ to match management system load requirements. The battery system reconfiguration can be based on removing, replacing, or adding battery units, power request parameters, and so on.

In some applications, the series switch can comprise a switch pair with a switch in the anode power connection of each battery unit and a switch in the cathode power connection of each battery unit. The switch in each anode power connection and the switch in each cathode power connection can be operated in tandem such that the anode power connection and the cathode power connection can be either both open or both closed. When the switch pair is in the open position, the battery unit is isolated from the power bus, and when the switch pair is in the closed position, the battery unit is connected to the power bus. Each battery unit switch pair can be electronically controlled by a master controller. The master controller can control electronically controlled switches, such as the switch pairs, in order to configure the battery system. The configuration can include setting the battery system to meet voltage, current, and run time, etc., targets.

Each battery unit can be bypassed by a shunt, or bypass, switch. The shunt switch can be used to include a battery unit for use within the battery system, or to bypass the battery unit. Bypassing the battery unit can be based on the battery unit not being required within a battery system configuration to meet battery system voltage, current, or runtime requirements. The bypassing can be used when the battery unit is operating below performance requirements, failing, experiencing elevated temperature or decreased battery cell impedance, being designated for service, being charged in situ, and so on. Each shunt switch can be electronically controlled by the master controller. The controlling of the shunt switch can be coordinated with controlling the series switch such that when the shunt switch is open, the series switch is closed, or when the shunt switch is closed, the series switch is open. Deadtime control can be implemented to prevent both the bypass shunt switch and the series switch or switch pair from being open or closed at the same time. Each shunt switch enables the power bus to bypass a selected battery unit. The bypassing can be used to exclude the selected battery unit from a configuration, to prepare the battery unit for replacement, and the like.

The battery system can include effecting an in situ battery unit reconfiguration, using the master controller. The battery unit reconfiguration can be implemented by selectively opening or closing shunt switches, series switches, series switch pairs, and so on. The reconfiguration can be based on changes in battery unit characteristics, power load fluctuations, etc. The reconfiguration can be implemented in response to a request such as request from a user, an external system request, and so on. The request can also originate from a battery cell, battery unit, or a column or system failure. The reconfiguration can further be based on balancing energy storage between battery cells, units, columns, systems, etc.; a voltage level; temperature; current; etc. The request can result from energy loads exceeding a threshold, storage capacity, safety limits, and so on. The reconfiguring can include a different voltage arrangement for charging battery units than a voltage arrangement for discharging battery units. The reconfiguring can adjust the voltage down for charging to, for example, 40V, 50V, and so on Likewise, the reconfiguring can increase the battery system voltage for providing energy to, for example, 600V, 900V, and the like. The reconfiguring can be accomplished dynamically. A built-in electrical design can be provided within the electronically controlled switches (e.g., flyback diodes) to smooth voltage and current spikes in order to avoid damage to appliances and other loads. In embodiments, the master controller initiates the effecting, based on the battery unit performance and a software-defined system goal. The software-defined system goal can be provided by a user, downloaded over a computer network, and so on. The software-defined system goal can include voltage and current requirements, operating temperature ranges, a duration of time for providing energy without recharging battery units, etc.

Various steps in the flow 100 may be changed in order, repeated, omitted, or the like without departing from the disclosed concepts. Various embodiments of the flow 100 can be included in a computer program product embodied in a non-transitory computer readable medium that includes code executable by one or more processors. Various embodiments of the flow 100, or portions thereof, can be included on a semiconductor chip and implemented in special purpose logic, programmable logic, and so on.

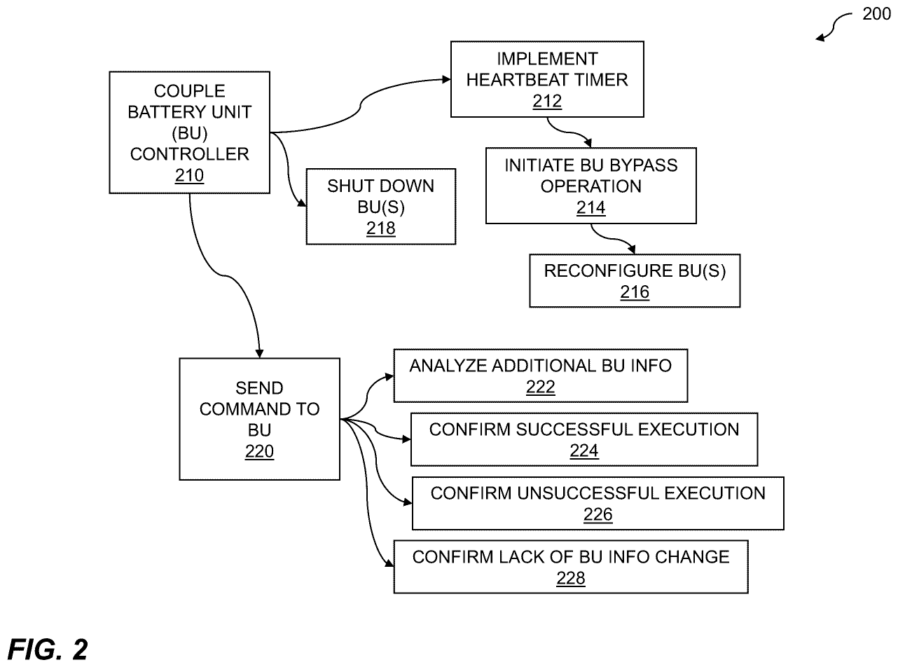

FIG. 2 is a flow diagram for battery unit handling. The flow 200 includes coupling a battery unit controller 210 to each battery unit of the plurality of battery units. In embodiments, the battery unit controller 210 can include a local memory cache. The local memory cache can be used to store information from the battery sensors connected to the associated battery unit. The battery unit controller can report sensor data from the local memory cache to the master controller. In some embodiments, the sensor data can be reported to the master controller when the master controller sends a heartbeat poll signal to the battery unit controller. In embodiments, the battery unit controller can include a heartbeat timer 212, wherein the heartbeat timer is programmable by the master controller. A heartbeat is a periodic signal generated by hardware or software such as the battery master controller. The heartbeat signal can be used to indicate normal operation or to synchronize functions within a system. In embodiments, the heartbeat timer can be reset upon receiving a poll from the master controller. In some embodiments, the battery unit controller can respond to the heartbeat poll signal from the master controller with a simple acknowledgement signal (ACK) or with the most recent set of sensor values from the local memory cache.

In the flow 200, the battery unit controller can include initiating a battery unit bypass operation 214, by the battery unit controller, based on heartbeat timer expiration. At the beginning of each heartbeat poll cycle, a heartbeat timer in the battery unit controller is reset by receiving a poll signal from the master controller. The heartbeat timer begins to run in the battery unit controller, waiting for the next poll signal from the master controller. The length of time between each heartbeat poll signal from the master controller can be programmable and can be set by the master controller. Each time a heartbeat poll signal is received from the master controller, the heartbeat timer on the battery unit controller is reset. If the heartbeat poll signal from the master controller is received by the battery unit controller after the programmed interval or not at all, the battery unit controller can initiate a battery unit bypass operation.

In embodiments, each battery unit in the plurality of battery units can include a series switch. In some applications, the series switch can comprise a series switch pair, which includes a switch coupled to an anode power connection to a battery unit, and a switch coupled to a cathode power connection to a battery unit. The battery unit switch pair can be electronically controlled by the master controller and by the local battery unit controller. The flow 200 can include connecting a bypass, or shunt, switch across each battery unit. The bypass shunt switch can be used to include a battery unit for use within the battery system or to bypass the battery unit. The bypassing the battery unit can be based on the battery unit not being required within a battery system configuration to meet battery system voltage, current, or runtime requirements. The bypassing the battery unit can be used when the battery unit is operating below performance requirements, failing, experiencing elevated temperature or decreased battery cell impedance, being designated for service, and so on. The bypassing the battery unit can be used when the heartbeat poll signal from the master controller is not received by the battery unit controller in time or is not received at all. Each bypass shunt switch can be electronically controlled by the master controller. The bypass shunt switch for each individual battery unit can be electronically controlled by its associated local battery unit controller. The controlling of the bypass shunt switch can be coordinated with the controlling of the series switch such that when the bypass shunt switch is open, the series switch is closed, or when the bypass shunt switch is closed, the series switch is open. Deadtime control is implemented to prevent both the bypass shunt switch and the series switch or switch pair from being open or closed at the same time, causing a potential short circuit condition. Each bypass shunt switch enables the power bus to bypass a selected battery unit.

In the flow 200, the battery unit bypass operation includes reconfiguring 216 the plurality of battery units to accommodate results of the bypass operation. The flow 200 can include effecting an in situ battery unit reconfiguration, using the master controller. The battery unit reconfiguration can be implemented by selectively opening and/or closing shunt switches and series switches. The reconfiguration can be based on changes in battery unit characteristics, power load fluctuations, and so on. The reconfiguration can be based on a late or missed heartbeat poll signal from the master controller to a battery unit controller. The reconfiguration can be implemented in response to a request such as request from a user, an external system request, and so on. The request can also originate from a battery cell battery unit or a column or system failure. The reconfiguration can further be based on balancing energy storage between battery cells, units, columns, systems, etc.; a voltage level; temperature; current; etc. The request can result from energy loads exceeding a threshold, storage capacity, safety limits, and so on. The reconfiguring can include a different voltage arrangement for charging battery units than a voltage arrangement for discharging battery units. The reconfiguring can adjust the voltage down for charging to, for example, 40V, 50V, and so on. Likewise, the reconfiguring can increase the battery system voltage for providing energy to, for example, 600V, 900V, and the like. The reconfiguring can be accomplished dynamically. A built-in electrical design can be provided within the electronically controlled switches (e.g., flyback diodes) to smooth voltage and current spikes in order to avoid damage to appliances and other loads. In embodiments, the master controller initiates the effecting, based on the battery unit performance and a software-defined system goal. The software-defined system goal can be provided by a user, downloaded over a computer network, and so on. The software-defined system goal can include voltage and current requirements, operating temperature ranges, a duration of time for providing energy without recharging battery units, etc.

In the flow 200, coupling a battery unit controller to each battery unit of the plurality of battery units can also include shutting down one or more of the plurality of battery units 218, if communication with one or more of the battery unit controllers is lost. Based on programmed configurations, the master controller can shut down the entire battery system relative to conditions indicated by a plurality of battery unit controllers. These conditions could include, for example, the number of remaining battery units being connected to the power bus not being configured to meet the requirements of the programmed battery output, or the temperature conditions of a plurality of battery units indicating a system-wide environment problem.

The flow 200 can include sending a command 220 to a battery unit within the plurality of battery units. The signal communication path can be based on one or more communication techniques such as wired techniques, wireless techniques, fiber-based techniques, and so on. The communication techniques can include Ethernet™, EtherNet/IP™, EtherCAT™, 802.11, Zigbee™, near-field communication (NFC), and so on. The communications standards can also include fiber distributed data interface (FDDI), fiber channel, asynchronous transfer mode (ATM), etc. The communications techniques can further include Industrial Internet of Things (Industrial IoT, IIoT). In embodiments, the command can include a signal to one or more switches on the battery unit to connect or bypass the unit. The signal can be a heartbeat poll, a heartbeat reset, and so on. The flow can include providing a signal communication path between the master controller and each battery unit.

In embodiments, the command can be sent from the master controller using the signal communication path. The command can be sent in response to analyzing battery unit information, wherein the analyzing determines a battery unit metric. In some embodiments, a capability metric for the battery cell can be predicted based on the analyzing of the information on the one or more battery cells in a battery unit. The capability metric can include voltage, power, energy, or number of cycles. The capability metric for the battery cell can be aggregated with capability metrics from other cells from the plurality of cells, wherein the other cells reside within a same column as the battery cell for which the capability metric was predicted, to produce a battery unit capability metric. The analyzing can include additional battery unit information 222 from the battery unit within the plurality of battery units. The battery unit capability metric can be aggregated with capability metrics from other battery units to produce a battery system capability metric. The analyzing can include confirming successful battery unit command execution 224, based on the additional battery unit information. In embodiments, the communication between the master controller and the one or more battery units can include closed loop logic to ensure that the command has been successfully executed. In some embodiments, the voltage or current reading from the battery unit can be used to verify the success of the command sent from the master controller. In some embodiments, the heartbeat poll signal can be used to confirm successful execution of a command. For example, a normal response from a battery unit to a heartbeat poll can be used to confirm that a battery unit has successfully connected to an active configuration of a battery system. Likewise, a null response from a battery unit to a heartbeat poll can confirm that the battery unit has successfully disconnected from an active configuration and is offline or ready to be replaced.

The analyzing can include confirming unsuccessful battery unit command execution 226, based on the additional battery unit information. The analyzing can include confirming unsuccessful battery unit command execution, based on a lack of change of the battery unit information 228. As mentioned above, the voltage or current reading of a battery unit can be used to confirm or deny the successful completion of a command from the master controller. For example, a voltage reading can confirm that a battery unit is connected to an active battery system configuration. If the master controller sends a “Disconnect” signal to the battery unit and the voltage reading remains unchanged, the master controller can confirm an unsuccessful execution 226 of the disconnect command and can resend the signal. In some embodiments, a heartbeat poll signal can be used to confirm unsuccessful execution of a battery unit command. For example, a normal response from a battery unit to a heartbeat poll can be used to confirm that a battery unit has not disconnected from an active configuration of a battery system. Likewise, a null response from a battery unit to a heartbeat poll can confirm that the battery unit has not successfully connected to an active configuration and remains offline. In some embodiments, the heartbeat poll from the master controller can prompt a set of battery unit data values that are the same as those stored in the master controller system cache. The lack of change in battery unit information can be used to confirm that a battery unit command has not been successfully executed, prompting the master controller to resend the command to the battery unit.

Various steps in the flow 200 may be changed in order, repeated, omitted, or the like without departing from the disclosed concepts. Various embodiments of the flow 200 can be included in a computer program product embodied in a non-transitory computer readable medium that includes code executable by one or more processors. Various embodiments of the flow 200, or portions thereof, can be included on a semiconductor chip and implemented in special purpose logic, programmable logic, and so on.

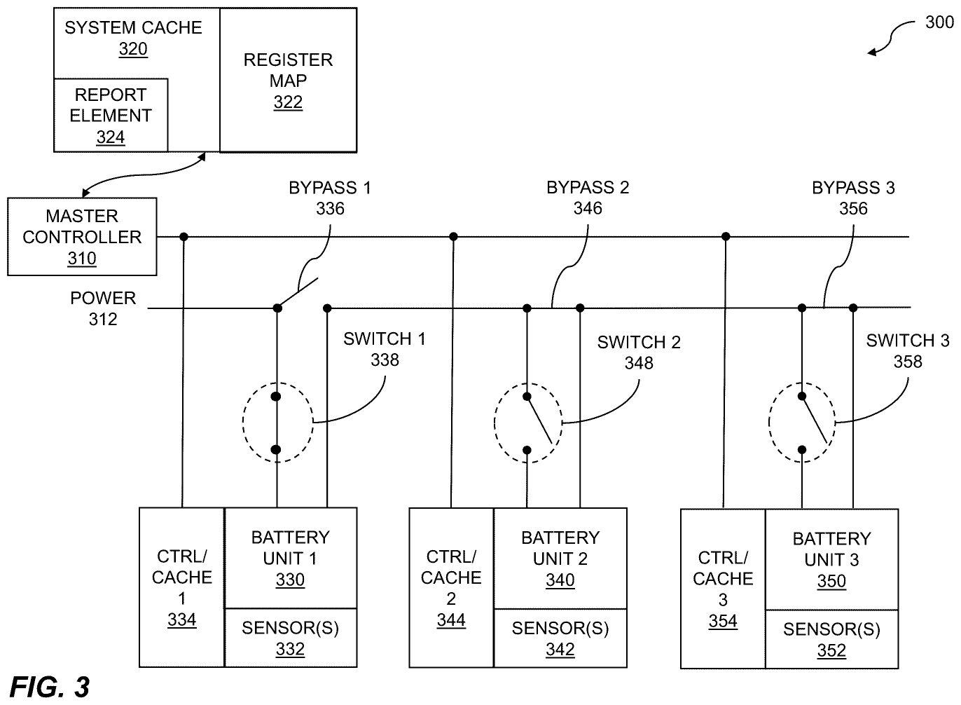

FIG. 3 is a system block diagram for battery management with low latency. The system block diagram 300 includes a master controller 310. The master controller can control electronically controlled switches, such as serial switches 338, 348, and 358, in order to configure the battery system. The configurating can include setting the battery system to meet voltage, current, and run time, etc., targets. The master controller can include a system cache 320, a register map 322, and a report element 324. In embodiments, the master controller stores battery unit information in a system cache. A cache is a hardware or software component that can store data in memory for rapid access at a later time. The battery unit information can first be stored in local caches for each battery unit. The battery unit information stored in each local cache can be reported to a master controller 310, wherein the master controller stores the battery unit information in the system cache 320. In embodiments, the system cache implements a register map 322. A register map is a dedicated memory area that contains values such as temperature, current, voltage, etc. The register map can contain values that correspond to the one or more battery units. The system cache can implement a last in first out (LIFO) data structure for the register map. Each battery unit can be assigned a set of registers in which the most recent value of each battery unit performance characteristic is stored. On startup of the battery units and master controller, the master controller can poll all of the battery units to collect each performance value and store them in the register map. More than one set of values can be stored for each battery unit in the register map. The LIFO data structure of the register map can be used to ensure that the most recent value for each performance value of each battery unit is the first value available for the master controller to read.

The report element 324 can be triggered by a change in the battery unit information. In embodiments, the triggers for the reporting can be based on one or more threshold settings. The one or more threshold settings can be provided at a battery unit granularity. The one or more threshold settings can also be provided at a sensor granularity. Once performance values have been stored in the master controller register map and the local cache for each battery unit, the heartbeat polling timer can be used to poll each battery unit periodically, such as every 2 milliseconds (ms), to check for any significant changes in any of the performance values. In some embodiments, when the sensors on the one or more battery units have not recorded a performance change, the local controller on the battery unit can reply “No Change” to the heartbeat poll request from the master controller. The heartbeat polling timer is then reset, and the master controller moves on to the next battery unit in the heartbeat polling cycle. In some embodiments, the local controller can report the most recent set of sensor readings to the master controller. The master controller can then compare the current sensor values to the values in its system cache and move forward if nothing has changed, or remove the battery unit from the active configuration if there is a problem.

The system block diagram 300 includes battery unit 1 330, battery unit 2 340, and battery unit 3 350. Greater or fewer numbers of battery units can be employed. Each battery unit can include one or more battery cells. Each battery unit can include or be coupled to one or more sensors, such as sensor(s) 332 for battery unit 1, sensor(s) 342 for battery unit 2, and sensor(s) 352 for battery unit. Each battery unit can include or be coupled to a local controller/cache, such as controller cache 1 334 for battery unit 1 330, controller/cache 2 344 for battery unit 2 340, and controller/cache 3 354 for battery unit 3 350. The battery units can include homogeneous battery cells, heterogeneous battery cells, and so on. The battery units can include battery cells with substantially similar physical dimensions, a mixture of battery cells with substantially different physical dimensions, etc. The battery cells, which can include rechargeable battery cells, can include a variety of battery types. In embodiments, the one or more battery cells can include lithium-ion battery cells. Other types of rechargeable cells, such as sealed lead-acid (SLA), nickel-cadmium (NiCd), nickel-metal hydride (NiMH), lithium-polymer (LiPo), lithium-iron-phosphate (LiFePO4), sodium-ion, lithium-metal, solid-state, sodium ion, zinc based, etc., can be included.

As mentioned above, battery unit information can be collected by local battery unit controller/caches 334, 344, and 354. Each local controller/cache can collect sensor data from the sensors with which it is associated, namely sensors 332, 342, and 352, respectively, for battery unit 1 330, battery unit 2 340, and battery unit 3 350. Information obtained from the battery system can include temperature, current, voltage, impedance, number of cycles, and so on. The most recent value for each of these characteristics can be stored in the local controller cache and updated as the various sensors on the battery unit monitor battery performance. In some embodiments, the values of previous cycles can be stored in cache memory as well for comparison. The battery performance values can also be forwarded to the master controller when requested, or when a change in one or more battery characteristics varies by a predetermined amount. For example, if the temperature of the battery unit changes by more than 2 degrees or voltage changes by more than 0.5 volts.

The system block diagram 300 can include programmable series switch 1 338, for configuring battery unit 1 330, programmable series switch 2 348, for configuring battery unit 2 340, and programmable series switch 3 358, for configuring battery unit 3 350. The switches can be used to couple, decouple, bypass, etc. the battery units. The battery sensors 332, 342, and 352 can be used to monitor battery performance information such as temperature, current, voltage, or impedance data. The programmable switches, which are based on high-speed switching devices, and the sensors can be monitored and controlled by a master controller 310 in order to operate the battery cells, battery units, and battery systems at their most efficient and safest levels. The safe battery levels can be monitored by a master controller that monitors battery levels and selectively disconnects battery units from the battery system before a battery unit failure. The master controller can direct the programmable switches to couple specific battery units or groups of battery units to achieve desired configurations. The battery cells and units can be monitored frequently in order to quickly respond to any detected problems.

In the system block diagram 300, the plurality of battery units, battery sensors, local controller/caches, battery switches, and a master controller can be combined to comprise a battery system. A battery system comprised of any combination of new or used battery units can be configured by a master controller 310 using electronically controlled switches 338, 348, and 358. The switches can connect the battery units into columns of units connected in series. The switches can also connect the columns in parallel to comprise the battery system. The electronically controlled switches can further connect or bypass each battery unit. The connections can be accomplished using series switches 338, 348, and 358 to connect or disconnect battery unit terminals to a power bus 312. The bypassing can be accomplished using a shunt, or bypass, switch to bypass a battery unit. In the system block diagram 300, bypass switch 1 336 bypasses battery unit 1 330, bypass switch 2 346 bypasses battery unit 2 340, and bypass switch 3 356 bypasses battery unit 3 350. The connecting or bypassing can be based on a power system configuration, where the configuration includes voltage and current levels, run times, etc. Battery unit performance information can be obtained on the battery units within the battery system including battery unit profile, safety information, temperature, current, voltage, impedance, charge/discharge cycle count, and so on. Information on the battery system can be provided by local controllers within each battery unit to the master controller. The master controller can reconfigure the battery system in situ to match and/or manage system power and/or load requirements. The battery system reconfiguration can be based on removing, replacing, or adding battery units, power request parameters, and so on.

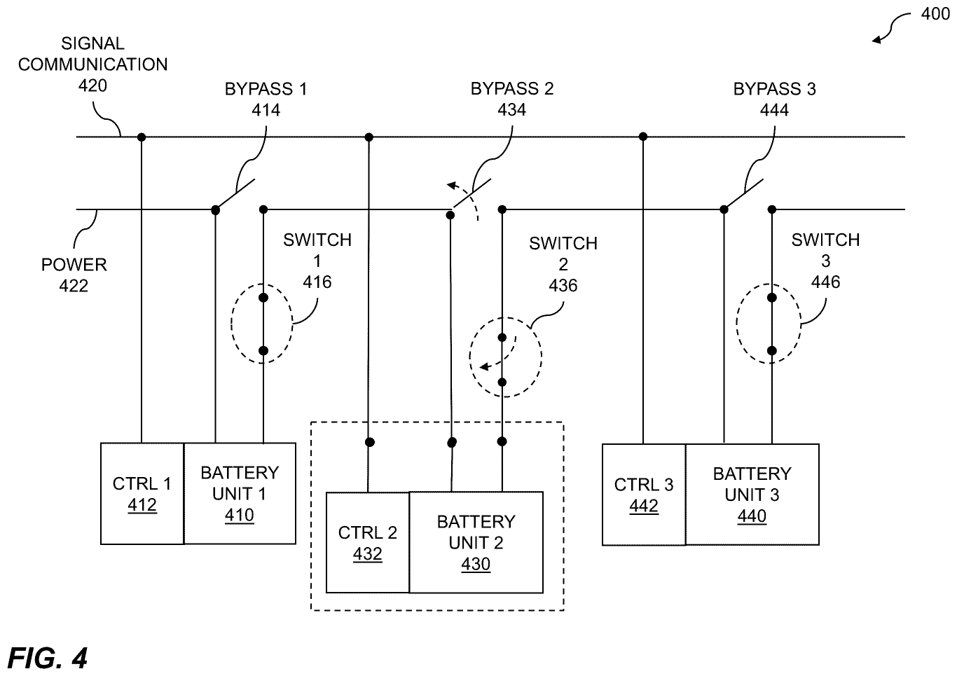

FIG. 4 illustrates battery unit replacement completion. A battery unit within a battery system can be replaced with a second battery unit. The battery unit replacement can be necessitated due to battery unit failure, battery cell combustion risk, routine maintenance, and so on. The replacement battery unit can be substantially similar to the replaced battery unit or substantially different from the replaced battery unit. The battery unit replacement completion can include configuring the placement battery unit for use within the battery system. The illustration 400 shows a battery system comprising three battery units, where replacement of one of the battery units has been completed. The battery units can include battery unit 1 410. The battery unit includes a local controller such as controller 1 412. The local controller can be in communication with a master controller (not shown) using a provided signal communication path 420. The communication path can be wireless, wired, optical, etc. The battery unit can further include electronically controlled switches which are controlled by the master controller. The switches can include a shunt switch such as bypass 1 414, which can be used to bypass battery unit 1. The switches can further include a series switch 1 416. The series switch can comprise a switch in the anode power connection of the battery unit and/or a series switch in the cathode power connection of the battery unit (only one switch is shown). If using a pair of switches, i.e., one in the anode leg and one in the cathode leg, the switches can be electronically controlled as a pair by the master controller. Configured as a switch pair, the switches can be both open or both closed to break or make connections to their respective battery unit terminals. The switch pair can be sequenced for application in high-inductance circuits, among other applications. In the case of battery unit 1 410, the bypass switch 414 is open and the series switch 416 is closed, thereby enabling connection of battery unit 1 410 to a power bus rail 422. In some embodiments, the battery unit can include a lock that can comprise an electromechanical interlock. The electromechanical interlock can lock the battery unit within the battery system during normal configuration and operation of the battery unit.

The illustration 400 can further include a replacement battery unit 2 430. The replacement battery unit has replaced a battery unit that was previously removed from the battery system configuration. The battery unit 2 430 can include local controller 2 432. The local controller can be in communication with a master controller (not shown) using a signal communication path 420. The battery unit can include switches such as electronically controlled switches. The switches can include a shunt switch such as bypass 2 434, which can be used to bypass battery unit 2 430. The shunt switch can transition from closed to open under control of the master controller. The opening of the shunt switch can, in part, complete replacement of a battery unit. The switches can further include series switch 2 436. The series switch can be electronically controlled by the master controller. In the case of battery unit 2 430, the series switch 436 can transition from open to closed, thereby enabling connection of the battery unit to the power bus 422. The shunt switch and series switch transitions are accomplished by the master controller. In embodiments, the new battery unit anode power connection and cathode power connection can be physically enabled or prevented under control of the master controller by actuating the series switch. In some embodiments, the battery unit can include an electromechanical interlock. The electromechanical interlock can be transitioned from an unlocked to a locked position by the master controller, thereby completing battery unit replacement within the battery system.

The illustration 400 can further include a third battery unit, battery unit 3 440. The battery unit 3 440 can include one or more rechargeable battery cells. The third battery unit further includes a local controller, such as controller 3 442. The local controller can monitor and configure the third battery unit based on communications with the master controller. The local controller can be in communication with the master controller using the signal communication path 420. The battery unit can further be selectively connected to the power bus 422. The battery unit 3 can include a shunt switch, such as bypass 3 444, which is in the open position. The battery unit 3 can further include series switch 3 446, which for battery unit 3 is in the closed position, thereby connecting battery unit 3 to the power bus 422. In some embodiments, the battery unit can include an interlock. The lock can be placed in a locked position so that battery unit 3 can be configured to deliver energy to the power bus.

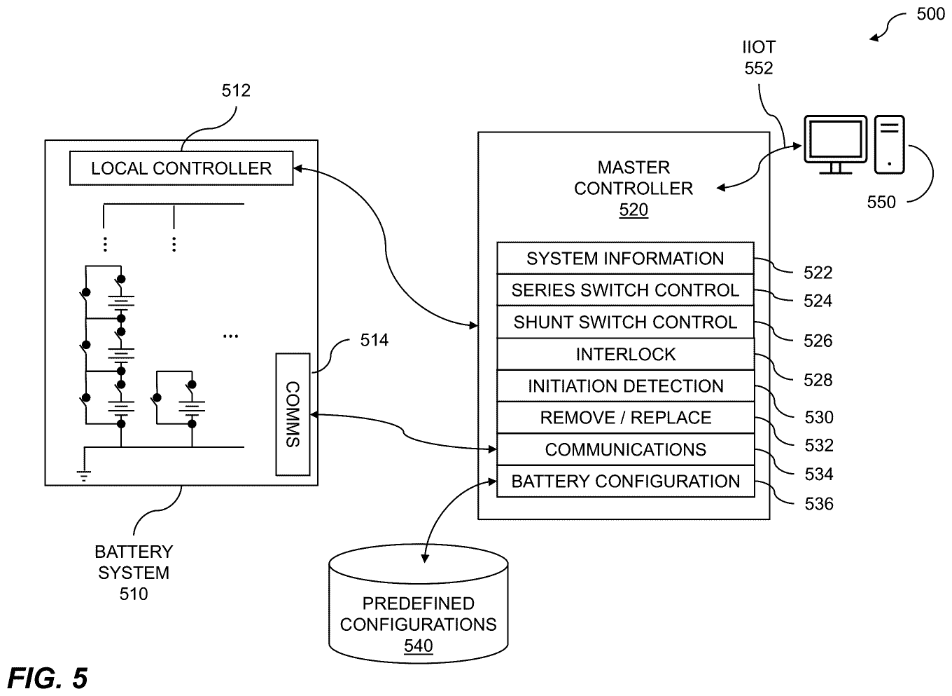

FIG. 5 is a system block diagram 500 for managing controlled replacement. A master controller can be used to control a battery system. The battery system can comprise a plurality of battery units, where a battery unit can include one or more battery cells; switches; sensors such as thermal, voltage, and current sensors; and so on. The master controller can generate a heartbeat poll signal to verify the status of each battery unit in the battery system. In embodiments, each battery unit of the plurality of battery units can include a local controller for communicating with the master controller. The local controller can monitor sensors associated with the battery unit; store sensor data in a local memory cache; send messages to the master controller; respond to the heartbeat poll signal sent by the master controller; send sensor data to the master controller; respond to commands, requests, etc. sent by the master controller; and so on. In embodiments, the local controller can sense battery unit performance characteristics. The local controller can process integrated button presses and actuate an electro-mechanical interlock component, etc., under control of the master controller. The local controller can store sensor data to a local memory cache. The local controller can send sensor data to the master controller. The local controller can communicate an event, such as a button press event, to the master controller using the signal communication path. The button press event can indicate the battery unit to be replaced. The signal communication path can be based on one or more communications standards, protocols, etc. The master controller can communicate with devices, systems, and so on beyond the battery system. In embodiments, the communications beyond the battery system can be enabled by an Industrial Internet of Things (IIoT) protocol. A Battery Management System (BMS) can determine the battery system configuration based on power requests to the system. The requests can be made by a user or can be accomplished automatically by a system requiring energy coupled to the battery system. The BMS can configure the battery system by determining how to direct the switches such as software-controlled switches to couple specific battery cells to achieve the desired configuration. The BMS can further provide battery system status information using protocols such as secure TCP/IP protocols.

The system block diagram 500 can include a battery system 510. The battery system is comprised of a plurality of battery units, where each battery unit can comprise a plurality of battery cells. The battery units are coupled to a plurality of software-controlled switches. In embodiments, each battery unit of the plurality of battery units can be connected in series to a power bus through a switch in each anode power connection of each battery unit and/or through a switch in each cathode power connection of each battery unit. A switch in the anode power connection of the battery unit and a switch in the cathode power connection of the battery unit comprise a battery unit switch pair, and each battery unit switch pair is electronically controlled by a master controller. The switches can couple the battery cells into a plurality of columns arranged in series. The switches can couple the columns in parallel, forming the battery system. The battery units can include rechargeable batteries, such as lithium-ion batteries, that have been removed from vehicles, energy storage devices, personal electronic devices, and so on, which can be reused for other applications. These batteries can be considered used, previously used, preowned, “second life”, etc. The battery system can include a local controller (LC) 512, which can determine whether a battery cell is usable, available, required, etc. by the system. In embodiments, the local controller senses battery unit performance characteristics. The performance characteristics can include battery unit storage capacity, energy delivery capabilities, internal temperature, combustion risk, and so on. The local controller can control the switches associated with the battery cells and battery columns to enable cells and columns, to bypass cells and columns, etc. The control of the switches can be orchestrated by a master controller (discussed below). The battery system can include a communications element 514. The communications element can be incorporated into the local controller, coupled to the local controller, etc. The communications element can communicate with the master controller. The communications element can use a signal communication path between the master controller and each battery unit. The communication path can include a wired, wireless, or fiber-based path.

The system block diagram 500 can include a master controller (MC) 520. The MC can monitor and control operation of one or more battery systems. The MC can obtain battery system status information 522. The battery system status information can include the state of battery unit charge; sensor data such as voltage, current, and battery cell temperature data; and so on. The MC can perform series switch control 524. The master controller can control anode power connection series switches and/or cathode power connection series switches associated with the one or more battery units within the battery system. The series switches can connect a battery unit to a power bus. The connection of the battery unit to the power bus can be a series connection. The MC can control shunt switches 526 associated with the one or more battery units. A shunt switch associated with a battery unit can enable the power bus to bypass a selected battery unit. The shunt switch and the series switch associated with a battery unit can be operated in tandem. In a usage example, the series switch is opened and the shunt switch is closed to electrically isolate the battery unit from the power bus. The electrical isolation can be used to disconnect a battery unit when not in use, to prepare the battery unit for removal or replacement, etc.

The master controller 520 can implement a heartbeat timer (not shown). A heartbeat is a periodic signal generated by hardware or software such as the battery master controller. The heartbeat signal can be used to indicate normal operation or to synchronize functions within a system. For example, the master controller can send a heartbeat poll signal to battery unit 1, followed by battery unit 2, then battery unit 3, and so on. In some embodiments, the local battery unit can reply with an OK signal to acknowledge the heartbeat signal. In some embodiments, the local battery unit controller 512 can reply with the most recent set of sensor values, or with one or more sensor values that have changed from the previous status check. The heartbeat request can be sent from the master controller to the battery unit within a specific length of time, and the response can come back from the battery unit within a specific length of time as well. A late response from the battery unit can be interpreted as a no response and the master controller can send signals to the appropriate switches to remove the battery unit from the active battery system configuration. Likewise, a late heartbeat signal from the master controller can also be interpreted as a fault in the battery system, leading to the battery unit activating switches to remove itself from the active battery configuration. The heartbeat timer can be programmed by the master controller 520. The heartbeat timer can be reset upon receiving a poll from the master controller. The battery unit controller can initiate a battery unit bypass operation, based on heartbeat timer expiration, further comprising reconfiguring the plurality of battery units to accommodate the results of the bypass operation. A plurality of battery units can be shut down, based on lost communication with one or more of the battery unit controllers.

The master controller can control interlocking 528 the one or more battery units within the battery system. The interlocking can be used to enable or disable battery security, removal, replacement, addition, and so on. Further embodiments can include electromechanically interlocking each battery unit of the plurality of battery units. The interlocking can be part of configuring the battery system (discussed below). The interlocking can be accomplished using an electromechanical lock such as a solenoid actuated lock. The MC can include an initiation detection element 530. The initiation detection element can detect a signal, flag, message, etc., that can indicate initiation of a battery unit addition, removal, replacement, etc. The MC can enable removal and replacement 532 of battery units within the battery system. The removal and replacement of a battery unit can include a sequence such as a control sequence. In embodiments, a master controller replacement sequence can be initiated by a manual action on a battery unit to be replaced. The manual action can be performed by an individual. In embodiments, the manual action can include pressing a button integrated in the battery unit to be replaced. The manual action can include a sliding action, a rotating action, etc. The MC can enable communications 534. The communications can occur between the master controller and a communications element associated with a battery system. The communications can be based on standard electronic communications standards such as 802.11, Bluetooth™, Zigbee, etc.

The master controller can enable battery configuration 536. Battery configuration can include configuring one or more battery units within the battery system. The configuration can include configuring the battery system to provide a voltage, a current, and an amount of energy; a duration of time to provide voltage, current energy, etc.; and so on. The battery configuration can include connecting or disconnecting individual battery units within the battery system. The battery configuration can be based on one or more predefined battery configurations 540. The standard configurations can be based on voltage, current, energy, and so on. The standard configurations can be based on an application. In a usage example, a predefined configuration can configure the battery system to provide backup power to a dwelling. An AC voltage can be obtained by coupling the battery system to an inverter (not shown).

The MC can effect in situ battery unit configuration, reconfiguration, and so on. In embodiments, the in situ battery unit reconfiguration can enable real-time power capability adjustment for the plurality of battery units. The real-time power capability adjustment can be based on periodic sampling of battery system capability, load requirements, and so on. In embodiments, the real-time power capability adjustment can provide matching between battery unit performance and battery management system load requirements. The MC can control adding a battery unit to a battery system, removing a battery unit, replacing a battery unit, etc. In embodiments, the master controller can enable a battery unit hot swap operation. The MC can further operate physical retainment of battery units within a battery system. Further embodiments include electromechanically interlocking each battery unit of the plurality of battery units as part of the configuring. The electromechanical interlock is controlled by the master controller. The master controller can communicate with a communications device 550. The communications device can be remote from the master controller and can be employed by a user to communicate with the battery system. The communications device can comprise a computer, laptop, tablet, cellphone, PDA, and the like. In embodiments, the communications device is another battery system, power grid, charging station, etc. which can negotiate power requirements directly with the battery system. Communication between the communications device and the master controller can be accomplished using a variety of electronic communications techniques. The communication can be accomplished over an industrial grade hardware interface such as CAN, RS485, Modbus, etc. In embodiments, the MC enables an Industrial Internet of Things (IIoT) 552 capability for the battery system to enable business-to-business communications over the Internet.

Other communications protocols can be supported. The MC can support protocols such as Simple Object Access Protocol (SOAP), Representational State Transfer (REST), and so on. The MC can support queries from the communications device to the battery system. For example, the MC can support a query to supply system information. The system information can include battery cell profiles, system status, temperature, current, voltage, power cycle information, and so on. The MC can provide information based on a query of capabilities of the battery system. The capabilities can include features, number, and health of battery cells; voltage output range; power capacity of the battery system; total energy; and so on. The MC can also provide information based on a query on availability of output from the battery system. An availability of output query can include information on the readiness of the system, charging time required, time until a charge is needed, and so on. In cases where one of the battery cells in the battery system fails, has degrading performance characteristics, represents a safety risk, etc., the MC can decommission a battery cell, column, portion, region, etc. of the battery system. The decommissioning can disable one or more battery cells in the system. The MC can include the ability for a user or system to provide power request parameters to the battery system. The power request parameters can include voltage, power, total energy, external system operating requirements, internal system operating requirements, user settings, or user preferences.

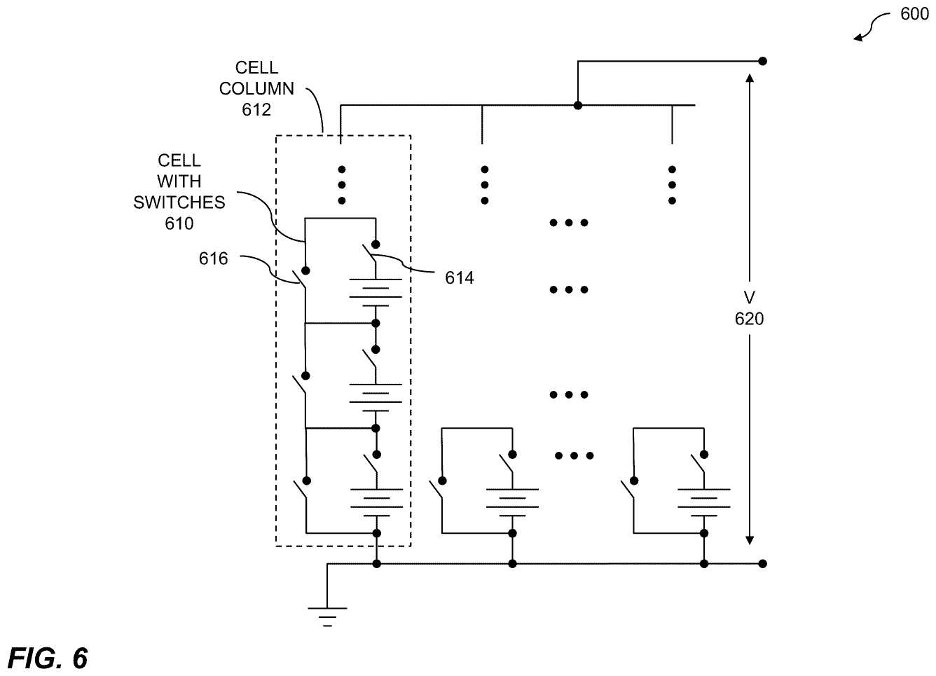

FIG. 6 illustrates columns of battery cells and switches in a battery system. Discussed above and throughout, clusters of battery cells can be grouped into battery columns, and battery columns can be grouped into a battery system. An individual battery cell can be coupled to or decoupled from a battery column of which the cell is a component. Similarly, a battery column can be coupled to or decoupled from a battery system. The decoupling can be accomplished by bypassing the battery cell, the battery column, etc. The coupling and bypassing can be accomplished using high-speed switches such as high-speed smart switches. The smart switches enable battery performance tracking across battery cells. A battery system comprising a plurality of battery cells is accessed, wherein the plurality of battery cells comprises a plurality of battery columns made up of battery cells arranged in series, wherein the plurality of battery columns is connected in parallel. Information on a battery cell within the plurality of battery cells is obtained, wherein the battery cell information is obtained using near field communication (NFC). The information on the battery cell is tracked by a column controller for a battery column from the plurality of battery columns, wherein the battery cell resides within the battery column. The information on the battery cell is stored for future reference. The information on the battery cell that was stored is analyzed. A capability metric is predicted for the battery cell based on the analyzing of the information on the battery cell.

A battery system comprising battery cells and switches is illustrated 600. The battery system can include one or more columns of grouped battery cells such as battery cell column 612. The battery columns can include one or more battery cells with switches, such as battery cell 610, with bypass switch 616 and series switch 614. In embodiments, the cluster of battery cells in a battery column includes battery cells connected in series. Each battery cell within a battery column can be coupled to or decoupled from the battery column using switches. The switches, such as switch 614 and switch 616, can accomplish coupling and decoupling under control of a controller. In embodiments, the switches can include smart switches. A battery cell can be coupled to or grouped with other battery cells to form a battery column. A battery cell can be decoupled from a battery column if the battery cell is unneeded, is performing poorly, has failed, and so on. In embodiments, the decoupling can accomplish the bypassing of a battery cell. Similarly, a battery column within a battery system can be coupled to or decoupled from the battery column. As for an individual battery cell, the decoupling can accomplish the bypassing of a battery column. The coupling switches and the bypass switches can be controlled by a controller component of a battery management system. The battery management system (discussed below) can measure the state for each battery cell, and can determine whether a battery cell is usable, available, and required by the system. The battery management system can control the switches associated with the battery cells and battery columns to enable cells and columns, to bypass cells and columns, etc. The battery cells within the battery columns can produce a voltage V 620. The voltage can be based on increments of voltage, where an increment of voltage can be determined by a voltage associated with a battery cell.

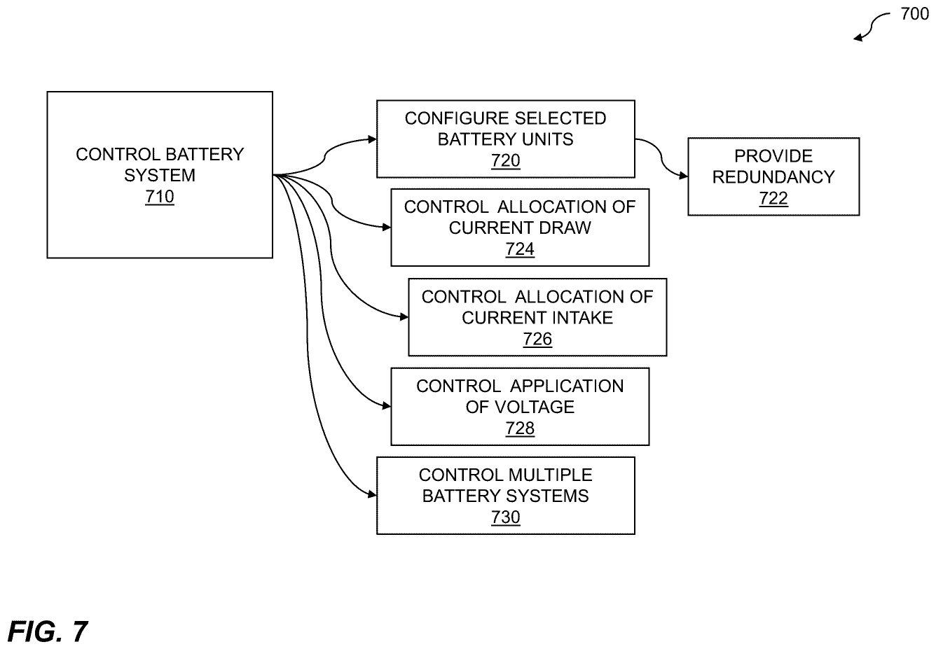

FIG. 7 is a flow diagram for battery system control. Batteries included within a disparate battery system can be controlled. Rechargeable batteries such as lithium-ion batteries that have been removed from vehicles, energy storage devices, personal electronic devices, and so on can be reused for other applications. These batteries can be considered used, previously used, preowned, “second life”, second hand, or can be described with some other terminology denoting a second usage. Such batteries can be well capable of functioning in certain capacities and usages. While the batteries may no longer meet their original specifications with respect to energy storage, leakage, and so on, the batteries can still store and provide energy for other applications. In order to use such “second life” batteries, the batteries can be disassembled down to their battery cells. Switches and scanners or sensors can be coupled to the battery cells. The switches can be used to couple, decouple, and bypass the battery cells, while the scanners and sensors can be used to monitor battery performance information such as temperature and/or temperature rate of change, current, voltage and/or voltage rate of change, or impedance data. The switches, which are based on high-speed switching devices, and the scanners can be controlled in order to operate the battery cells, battery units, and battery systems at their most efficient and safest levels. The safe battery levels can be monitored by a failsafe system that monitors safe battery levels and selectively disconnects battery units from the battery system before a battery unit failure. The battery cells, units, and systems can be monitored frequently in order to quickly respond to any detected problems. The monitoring and response enable battery performance tracking across battery cells.

The flow 700 includes controlling 710 the battery system. The controlling the battery system can include scanning battery units, where battery units contain one or more battery cells. The control can further include analyzing battery units to determine usability and capacity of the battery units. The controlling can include coupling or decoupling battery cells within battery units to the battery units, coupling or decoupling battery units within a battery system, coupling or decoupling battery systems within a plurality of battery systems, and so on. The controlling can collect battery unit performance information from the battery units. In the flow 700, the controlling the battery system can configure 720 selected battery units. Selected battery units can include battery units that have been identified, based on the analyzing, to have sufficient usability and capacity, such as storage capacity, to be used within a battery system. In the flow 700, the configuring the selected battery units provides redundancy 722 for the battery system. The redundancy can be based on storage capacity, battery system reliability, a backup power requirement, a safety factor, and so on. In embodiments, redundancy can be accomplished using an extra number of battery units in a column of battery units. The extra battery units can be switched in as needed to replace exhausted battery units, failed battery units, etc. In embodiments, the redundancy can provide for maintaining capacity. Capacity, such as storage capacity, can be maintained by switching in additional battery units as needed. Battery units can be switched in, switched out, bypassed, and so on. In other embodiments, the redundancy can provide for increasing reliability of the battery system. The redundancy can be based on N+1 redundancy, where N is the number of battery units required by a battery system plus one spare. The spare can be switched in as needed. Another redundancy scheme can include 2N redundancy.

In the flow 700, the controlling the battery system controls allocation 724 of current drawn from a subset of battery units from the plurality of battery units during a discharge event. The discharge event can include providing current to one or more loads. The discharge event can be based on providing constant voltage or constant current. In other embodiments, a discharge event can include a safety discharge event. A safety discharge event can occur when a battery cell or battery unit has failed, overheated, etc. The battery unit or cell can be safely discharged in order to avoid risk of fire or explosion in the battery unit or cell. In the flow 700, the controlling the battery system controls the allocation of current intake 726 to a subset of battery units from the plurality of battery units during a charge event. Current intake can be associated with charging battery cells, battery units, and a battery system. The charging of batteries can be based on providing constant current, variable current, constant voltage, variable voltage, etc. In embodiments, the battery system controls application of voltage 728 coupled to the subset of battery units from the plurality of battery units during a charge event. A technique used for the charging of batteries can be selected based on battery type. In the flow 700, the battery system further comprises controlling multiple connected battery systems 730. The multiple connected battery systems can be controlled by connecting or disconnecting one or more battery systems to maintain capacity, to provide redundancy, etc.

Various steps in the flow 700 may be changed in order, repeated, omitted, or the like without departing from the disclosed concepts. Various embodiments of the flow 700 can be included in a computer program product embodied in a non-transitory computer readable medium that includes code executable by one or more processors. Various embodiments of the flow 700, or portions thereof, can be included on a semiconductor chip and implemented in special purpose logic, programmable logic, and so on.

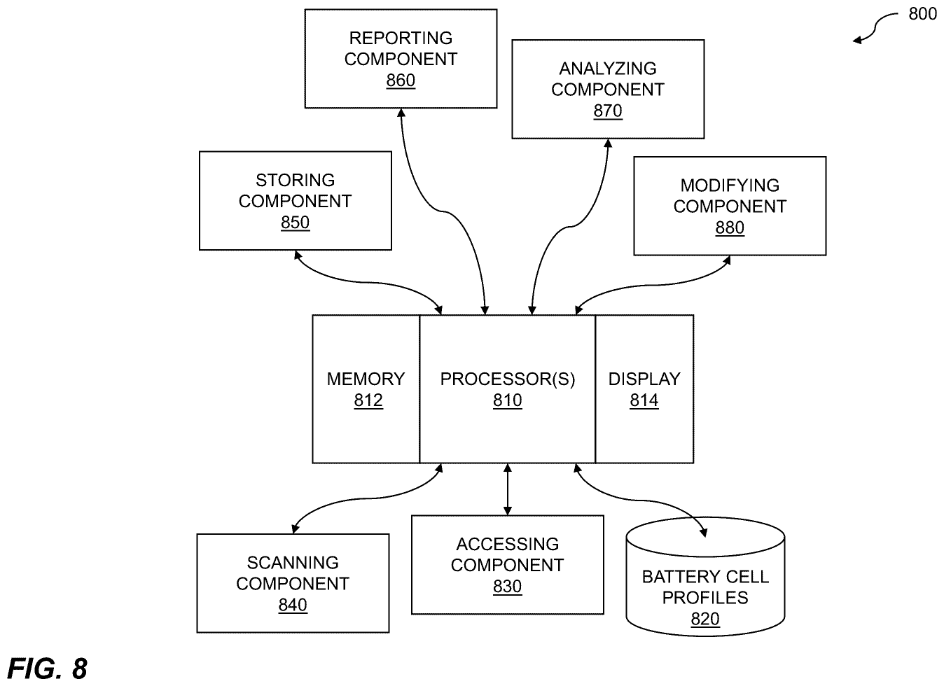

FIG. 8 is a system diagram for a battery management system with low latency. The system 800 can include one or more processors 810 and a memory 812 which stores instructions. The memory 812 is coupled to the one or more processors 810, wherein the one or more processors 810 can execute instructions stored in the memory 812. The memory 812 can be used for storing code along with storing battery unit configurations, performance information, battery usability and capacity data, battery state, predicted capacity metric for a battery, remaining energy, and the like. The battery unit data, configurations, performance information, etc. can be shown on a display 814 connected to the one or more processors 810. The display can comprise a television monitor, a projector, a computer monitor (including a laptop screen, a tablet screen, a netbook screen, and the like), a smartphone display, a mobile device, or another electronic display. The system 800 can include a computer system for battery management comprising: a memory which stores instructions; one or more processors coupled to the memory wherein the one or more processors, when executing the instructions which are stored, are configured to: access a plurality of battery units, wherein the battery units contain one or more battery cells, wherein the plurality of battery units is configured using programmable switches, and wherein the battery units are each monitored by one or more battery sensors; scan the battery units within the plurality of battery units to collect battery unit information; store the battery unit information in local caches, wherein each of the plurality of battery units has a local cache; report the battery unit information from each of the local caches to a master controller, wherein the master controller stores the battery unit information in a system cache, and wherein the reporting is triggered by a change in the battery unit information; analyze the battery unit information, wherein the analyzing determines a battery unit metric; and modify the battery unit configuration, based on the metric.

The system 800 can include battery cell profiles 820. The battery cell profiles 820 can include data associated with batteries that can form battery units, which can in turn form the battery system. The battery cell information can include physical parameters associated with the batteries, such as size, shape, weight, terminal configuration, battery chemical type, and so on. The battery cell information can include battery cell manufacturer information, usage hours, battery cell temperature, and the like. The system 800 can include an accessing component 830. The accessing component 830 can include accessing a plurality of battery units, wherein the battery units contain one or more battery cells, wherein the plurality of battery units is configured using programmable switches, and wherein the battery units are each monitored by one or more battery sensors. In embodiments, the plurality of battery cells can include homogeneous battery cells, heterogeneous battery cells, and so on. The battery cells can include substantially similar physical dimensions, a mixture of battery cells with substantially different physical dimensions, etc. The battery cells, which can include rechargeable battery cells, can include a variety of battery types. In embodiments, the one or more battery cells can include lithium-ion battery cells. Other types of rechargeable cells, such as sealed lead-acid (SLA), nickel-cadmium (NiCd), nickel-metal hydride (NiMH), lithium-polymer (LiPo), lithium-iron-phosphate (LiFePO4), sodium-ion, lithium-metal, solid-state, sodium ion, zinc based, etc., can be included.

In embodiments, programmable switches can be configured with the battery units. The switches can be used to couple, decouple, and bypass the battery units. The battery sensors can be used to monitor battery performance information such as temperature, current, voltage, or impedance data. The programmable switches, which are based on high-speed switching devices, and the sensors can be monitored and controlled by a master controller in order to operate the battery cells, battery units, and battery systems at their most efficient and safest levels. The safe battery levels can be monitored by a master controller that monitors battery levels and selectively disconnects battery units from the battery system before a battery unit failure. The master controller can direct the programmable switches to couple specific battery units or groups of battery units to achieve desired configurations. The battery cells and units can be monitored frequently in order to quickly respond to any detected problems.

The system 800 can include a scanning component 840. The scanning component can include scanning the battery units within the plurality of battery units to collect battery unit information. In embodiments, the scanning can be used to collect performance information associated with the battery units. The performance information can include various types of data associated with the battery units. In embodiments, the performance information can include temperature, current, voltage, or impedance data. The performance data can be collected prior to configuring a battery system, while a battery system is in use, and so on. The performance information can be evaluated at various levels including a battery cell, a battery unit, a battery unit column, the battery unit system, etc. Obtaining information can be accomplished by software-controlled switches, smart switches, scanners, sensors, etc., can be added to the cells to monitor cell “health”, and so on. In some embodiments, the obtaining information can be based on using battery unit profiles. The battery unit profiles can be based on manufacturer specifications, acceptance testing, in situ system testing, collected sensor information, specified or collected electrical characteristics, specified or collected physical characteristics, and so on. In embodiments, the scanning can occur at a frequency greater than 500 Hz. This scan rate can allow each scan cycle to be completed in 2 milliseconds.

The scanning component 840 can include coupling a battery unit controller to each battery unit of the plurality of battery units, wherein the battery unit controller implements a heartbeat timer. The heartbeat timer can be programmable by the master controller. The heartbeat timer can be reset upon receiving a poll from the master controller. The battery unit controller can initiate a battery unit bypass operation, based on heartbeat timer expiration, further comprising reconfiguring the plurality of battery units to accommodate results of the bypass operation. In some embodiments, the scanning component can include shutting down the plurality of battery units, based on lost communication with one or more of the battery unit controllers.

The system 800 can include a storing component 850. The storing component 850 can include storing the battery unit information in local caches, wherein each of the plurality of battery units has a local cache. A cache is a hardware or software component that can store data in memory for rapid access at a later time. As mentioned above, battery unit information can be collected by battery unit controllers associated with each of the battery units. The local controllers can collect sensor data from sensors associated with the battery units. The battery unit characteristics can be used to generate battery unit profiles, where the profiles can be used to store information about the battery units. Information obtained from the battery system can include temperature, current, voltage, impedance, number of cycles, and so on. The most recent value for each of these characteristics can be stored in the local cache and updated as the various sensors on the battery unit monitor battery performance. In some embodiments, the values of previous cycles can be stored in cache memory as well for comparison. The battery performance values can also be forwarded to the master controller when requested, or when a change in one or more battery characteristics varies by a predetermined amount.

The system 800 can include a reporting component 860. The reporting component 860 can include reporting the battery unit information from each of the local caches to a master controller, wherein the master controller stores the battery unit information in a system cache, and wherein the reporting is triggered by a change in the battery unit information. In embodiments, the reporting is performed by the system cache. Triggers for the reporting are based on one or more threshold settings, wherein the one or more threshold settings are provided at a battery unit granularity. In some embodiments, the one or more threshold settings are provided at a sensor granularity.

In embodiments, the system cache implements a register map, wherein the register map corresponds to battery units. The system cache implements a last in first out (LIFO) data structure for the register map. A register map is a dedicated memory area that contains values such as temperature, current, voltage, etc. The register map corresponds to the one or more battery units. The system cache implements a last in first out (LIFO) data structure for the register map. Each battery unit is assigned a set of registers in which the most recent value of each battery unit performance characteristic is stored. On startup of the battery units and master controller, the master controller can poll all of the battery units to collect each performance value and record them in the register map. In some embodiments, more than one set of values can be stored for each battery unit in the register map. The LIFO data structure of the register map can be used to ensure that the most recent value for each performance value of each battery unit is the first value available for the master controller to read.

The system 800 can include an analyzing component 870. The analyzing component 870 can include analyzing the battery unit information, wherein the analyzing determines a battery unit metric. In embodiments, the battery unit metric can comprise a functional metric. The battery unit metric can comprise a reliability metric. The analyzing component can be used to analyze the battery units to determine usability and capacity based on the performance information. The usability and capacity data can be included in the battery profiles. The usability data can include whether a battery unit is available for configuration in a battery system, whether the battery unit has physical integrity, etc. The capacity data of the battery unit can include remaining capacity. The remaining capacity can be based on a percentage, a value, a threshold, and so on. As the battery units continue to be used in various configurations, additional battery information can be analyzed and compared to the battery profile. As battery unit performance values and characteristics are recorded by sensors and reported to the master controller, the reliability and remaining capacity of each battery unit can be calculated and reported to users.

The system 800 can include a modifying component 880. The modifying component 880 can include modifying the battery unit configuration, based on the metric. In embodiments, the modifying can further comprise sending a command to a battery unit within the plurality of battery units. The command can be sent from the master controller. The command can be sent in response to the analyzing. A battery unit can be removed from active service when one or more performance metrics fall below a predetermined threshold, or when a heartbeat poll response is too slow or non-existent. As mentioned above, the programmable switches on each battery unit can be used to connect or bypass each battery unit, based on the configuration set by the master controller. The connecting or bypassing can be based on a power system configuration, where the configuration includes voltage and current levels, run times, etc. Battery unit performance information can be obtained on the battery units within the battery system including battery unit profile, safety information, temperature, current, voltage, impedance, charge/discharge cycle count, and so on. Information on the battery system can be provided by local controllers within each battery unit to the master controller. The master controller can reconfigure the battery system in situ to match management system load requirements. The battery system reconfiguration can be based on removing, replacing, or adding battery units, power request parameters, and so on.

In embodiments, the modifying can further comprise analyzing additional battery unit information from the battery unit within the plurality of battery units and confirming successful battery unit command execution, based on the additional battery unit information. The analyzing additional battery unit information can include confirming unsuccessful battery unit command execution, based on the additional battery unit information. The analyzing additional battery unit information can include confirming unsuccessful battery unit command execution, based on a lack of change of the battery unit information. The communication between the master controller and the one or more battery units can include closed loop logic to ensure that the command has been successfully executed. In some embodiments, the voltage or current reading from the battery unit can be used to verify the success of the command sent from the master controller. In some embodiments, the heartbeat poll signal can be used to confirm successful execution of a command. For example, a normal response from a battery unit to a heartbeat poll can be used to confirm that a battery unit has successfully connected to an active configuration of a battery system Likewise, a null response from a battery unit to a heartbeat poll can confirm that the battery unit has successfully disconnected from an active configuration and is offline or ready to be replaced.

The system 800 can include a computer program product embodied in a non-transitory computer readable medium for battery management, the computer program product comprising code which causes one or more processors to perform operations of: accessing a plurality of battery units, wherein the battery units contain one or more battery cells, wherein the plurality of battery units is configured using programmable switches, and wherein the battery units are each monitored by one or more battery sensors; scanning the battery units within the plurality of battery units to collect battery unit information; storing the battery unit information in local caches, wherein each of the plurality of battery units has a local cache; reporting the battery unit information from each of the local caches to a master controller, wherein the master controller stores the battery unit information in a system cache, and wherein the reporting is triggered by a change in the battery unit information; analyzing the battery unit information, wherein the analyzing determines a battery unit metric; and modifying the battery unit configuration, based on the metric.

Each of the above methods may be executed on one or more processors on one or more computer systems. Embodiments may include various forms of distributed computing, client/server computing, and cloud-based computing. Further, it will be understood that the depicted steps or boxes contained in this disclosure's flow charts are solely illustrative and explanatory. The steps may be modified, omitted, repeated, or re-ordered without departing from the scope of this disclosure. Further, each step may contain one or more sub-steps. While the foregoing drawings and description set forth functional aspects of the disclosed systems, no particular implementation or arrangement of software and/or hardware should be inferred from these descriptions unless explicitly stated or otherwise clear from the context. All such arrangements of software and/or hardware are intended to fall within the scope of this disclosure.

The block diagrams and flowchart illustrations depict methods, apparatus, systems, and computer program products. The elements and combinations of elements in the block diagrams and flow diagrams show functions, steps, or groups of steps of the methods, apparatus, systems, computer program products and/or computer-implemented methods. Any and all such functions—generally referred to herein as a “circuit,” “module,” or “system”—may be implemented by computer program instructions, by special-purpose hardware-based computer systems, by combinations of special purpose hardware and computer instructions, by combinations of general-purpose hardware and computer instructions, and so on.

A programmable apparatus which executes any of the above-mentioned computer program products or computer-implemented methods may include one or more microprocessors, microcontrollers, embedded microcontrollers, programmable digital signal processors, programmable devices, programmable gate arrays, programmable array logic, memory devices, application specific integrated circuits, or the like. Each may be suitably employed or configured to process computer program instructions, execute computer logic, store computer data, and so on.

It will be understood that a computer may include a computer program product from a computer-readable storage medium and that this medium may be internal or external, removable and replaceable, or fixed. In addition, a computer may include a Basic Input/Output System (BIOS), firmware, an operating system, a database, or the like that may include, interface with, or support the software and hardware described herein.

Embodiments of the present invention are neither limited to conventional computer applications nor the programmable apparatus that run them. To illustrate: the embodiments of the presently claimed invention could include an optical computer, quantum computer, analog computer, or the like. A computer program may be loaded onto a computer to produce a particular machine that may perform any and all of the depicted functions. This particular machine provides a means for carrying out any and all of the depicted functions.

Any combination of one or more computer readable media may be utilized including but not limited to: a non-transitory computer readable medium for storage; an electronic, magnetic, optical, electromagnetic, infrared, or semiconductor computer readable storage medium or any suitable combination of the foregoing; a portable computer diskette; a hard disk; a random access memory (RAM); a read-only memory (ROM); an erasable programmable read-only memory (EPROM, Flash, MRAM, FeRAM, or phase change memory); an optical fiber; a portable compact disc; an optical storage device; a magnetic storage device; or any suitable combination of the foregoing. In the context of this document, a computer readable storage medium may be any tangible medium that can contain or store a program for use by or in connection with an instruction execution system, apparatus, or device.

It will be appreciated that computer program instructions may include computer executable code. A variety of languages for expressing computer program instructions may include without limitation C, C++, Java, JavaScript™, ActionScript™, assembly language, Lisp, Perl, Tcl, Python, Ruby, hardware description languages, database programming languages, functional programming languages, imperative programming languages, and so on. In embodiments, computer program instructions may be stored, compiled, or interpreted to run on a computer, a programmable data processing apparatus, a heterogeneous combination of processors or processor architectures, and so on. Without limitation, embodiments of the present invention may take the form of web-based computer software, which includes client/server software, software-as-a-service, peer-to-peer software, or the like.

In embodiments, a computer may enable execution of computer program instructions including multiple programs or threads. The multiple programs or threads may be processed approximately simultaneously to enhance utilization of the processor and to facilitate substantially simultaneous functions. By way of implementation, any and all methods, program codes, program instructions, and the like described herein may be implemented in one or more threads which may in turn spawn other threads, which may themselves have priorities associated with them. In some embodiments, a computer may process these threads based on priority or other order.

Unless explicitly stated or otherwise clear from the context, the verbs “execute” and “process” may be used interchangeably to indicate execute, process, interpret, compile, assemble, link, load, or a combination of the foregoing. Therefore, embodiments that execute or process computer program instructions, computer-executable code, or the like may act upon the instructions or code in any and all of the ways described. Further, the method steps shown are intended to include any suitable method of causing one or more parties or entities to perform the steps. The parties performing a step, or portion of a step, need not be located within a particular geographic location or country boundary. For instance, if an entity located within the United States causes a method step, or portion thereof, to be performed outside of the United States, then the method is considered to be performed in the United States by virtue of the causal entity.

While the invention has been disclosed in connection with preferred embodiments shown and described in detail, various modifications and improvements thereon will become apparent to those skilled in the art. Accordingly, the forgoing examples should not limit the spirit and scope of the present invention; rather it should be understood in the broadest sense allowable by law.

What is claimed is:

1. A processor-implemented method for battery management comprising:
accessing a plurality of battery units, wherein the battery units contain one or more battery cells, wherein the plurality of battery units is configured using programmable switches, and wherein the battery units are each monitored by one or more battery sensors;
scanning the battery units within the plurality of battery units to collect battery unit information;
storing the battery unit information in local caches, wherein each of the plurality of battery units has a local cache;
reporting the battery unit information from each of the local caches to a master controller, wherein the master controller stores the battery unit information in a system cache, and wherein the reporting is triggered by a change in the battery unit information;
analyzing the battery unit information, wherein the analyzing determines a battery unit metric; and
modifying the battery unit configuration, based on the metric.

2. The method of claim 1 wherein the system cache implements a register map.

3. The method of claim 2 wherein the register map corresponds to battery units.

4. The method of claim 2 wherein the system cache implements a last in first out (LIFO) data structure for the register map.

5. The method of claim 1 wherein the reporting is performed by the system cache.

6. The method of claim 1 wherein triggers for the reporting are based on one or more threshold settings.

7. The method of claim 6 wherein the one or more threshold settings are provided at a battery unit granularity.

8. The method of claim 6 wherein the one or more threshold settings are provided at a sensor granularity.

9. The method of claim 1 wherein the scanning occurs at a frequency greater than 500 Hz.

10. The method of claim 1 further comprising sending a command to a battery unit within the plurality of battery units.

11. The method of claim 10 wherein the command is sent from the master controller.

12. The method of claim 10 wherein the command is sent in response to the analyzing.

13. The method of claim 10 further comprising analyzing additional battery unit information from the battery unit within the plurality of battery units.

14. The method of claim 13 further comprising confirming successful battery unit command execution, based on the additional battery unit information.

15. The method of claim 13 further comprising confirming unsuccessful battery unit command execution, based on the additional battery unit information.

16. The method of claim 13 further comprising confirming unsuccessful battery unit command execution, based on a lack of change of the battery unit information.

17. The method of claim 1 further comprising coupling a battery unit controller to each battery unit of the plurality of battery units.

18. The method of claim 17 wherein the battery unit controller implements a heartbeat timer.

19. The method of claim 18 wherein the heartbeat timer is programmable by the master controller.

20. The method of claim 18 wherein the heartbeat timer is reset upon receiving a poll from the master controller.

21. The method of claim 18 further comprising initiating a battery unit bypass operation, by the battery unit controller, based on heartbeat timer expiration.

22. The method of claim 21 further comprising reconfiguring the plurality of battery units to accommodate results of the bypass operation.

23. The method of claim 17 further comprising shutting down the plurality of battery units, based on lost communication with one or more of the battery unit controllers.

24. A computer program product embodied in a non-transitory computer readable medium for battery management, the computer program product comprising code which causes one or more processors to perform operations of:
accessing a plurality of battery units, wherein the battery units contain one or more battery cells, wherein the plurality of battery units is configured using programmable switches, and wherein the battery units are each monitored by one or more battery sensors;
scanning the battery units within the plurality of battery units to collect battery unit information;
storing the battery unit information in local caches, wherein each of the plurality of battery units has a local cache;
reporting the battery unit information from each of the local caches to a master controller, wherein the master controller stores the battery unit information in a system cache, and wherein the reporting is triggered by a change in the battery unit information;
analyzing the battery unit information, wherein the analyzing determines a battery unit metric; and
modifying the battery unit configuration, based on the metric.

25. A computer system for battery management comprising:
a memory which stores instructions;
one or more processors coupled to the memory wherein the one or more processors, when executing the instructions which are stored, are configured to:
access a plurality of battery units, wherein the battery units contain one or more battery cells, wherein the plurality of battery units is configured using programmable switches, and wherein the battery units are each monitored by one or more battery sensors;
scan the battery units within the plurality of battery units to collect battery unit information;
store the battery unit information in local caches, wherein each of the plurality of battery units has a local cache;
report the battery unit information from each of the local caches to a master controller, wherein the master controller stores the battery unit information in a system cache, and wherein the reporting is triggered by a change in the battery unit information;
analyze the battery unit information, wherein the analyzing determines a battery unit metric; and
modify the battery unit configuration, based on the metric.
